(19) United States
(12) Patent Application Publication
(10) Pub. No.: US 2015/0117590 A1
(43) Pub. Date: Apr. 30, 2015

(54) Shift frequency demultiplier

(71) Applicant: IPGoal Microelectronics (Sichuan) Co., Ltd., Chengdu (CN)

(72) Inventor: Xiu Yang, Chengdu (CN)

(73) Assignee: IPGoal Microelectronics (Sichuan) Co., Ltd., Chengdu (CN)

(21) Appl. No.: 14/141,202

(22) Filed: Dec. 26, 2013

(30) Foreign Application Priority Data
Oct. 31, 2013 (CN) 201310522075.1

(51) Int. Cl. H03K 23/54

(52) U.S. Cl. CPC H03K 23/54
USPC 377/124

(57) ABSTRACT

A shift frequency demultiplier includes: an inverter; N-2 registers; and N-4 OR gates; wherein an output terminal of the No. N-2 register is connected to an input terminal of the inverter, an output terminal of the inverter is connected to an input terminal of the No. 1 register and input terminals of the OR gates; the output terminal of the No. 1 register is connected to another input terminal of the No. 1 OR gate, the output terminal of the No. N-4 register is connected to another input terminal of the No. N-4 OR gate; an output terminal of the No. 1 OR gate is connected to the input terminal of the No. 2 register, an output terminal of the No. N-4 OR gate is connected to the input terminal of the No. N-3 register whose the output terminal is connected to an input terminal of the No. N-2 register.

### CROSS REFERENCE OF RELATED APPLICATION

The present invention claims priority under 35 U.S.C. 119(a-d) to CN 201310522075.1, filed Oct. 31, 2013.

### BACKGROUND OF THE PRESENT INVENTION

1. Field of Invention

The present invention relates to a technical field of digital IC (integrated circuit), and more particularly to a shift frequency demultiplier.

2. Description of Related Arts

Generally, there are two kinds of frequency demultiplier: shift frequency demultiplier and counting frequency demultiplier.

Compared with the shift frequency demultiplier, control logic of the phase of the counting frequency demultiplier is more complex. Therefore, the counting frequency demultiplier is usually utilized in the frequency demultiplier for clock with medium or low frequency. The shift frequency demultiplier requires simple logic for satisfying sequence requirement in high frequency designs. Therefore, the shift frequency demultiplier is usually utilized in the frequency demultiplier for clock with high frequency. However, a disadvantage of the shift frequency demultiplier is that: clock quality after frequency demultiplication depends on an initial state of the register set and state transformation during operation. In case that unforeseen reasons lead to state error, the frequency demultiplication problems or even total error will be caused.

Referring to FIG. 1 of the drawings, a schematic view of a circuit of a conventional shift frequency demultiplier utilized in a fractional-6 frequency demultiplier is provided, wherein the conventional shift frequency demultiplier comprises six registers: R1, R2, R3, R4, R5 and R6; D is an input terminal of the register, Q is an output terminal of the register; each reset terminal of the register is connected to a system reset signal terminal; the system reset signal terminal sends a system reset signal RSTn to each of the registers for wholly resetting the registers at an initial state, in such a manner that all the registers are set to 1 or 0; each clock terminal CK of the register is connected to an output terminal of an external high frequency clock terminal; the output terminal of the external high frequency clock terminal sends a high frequency clock CLK1 to the clock terminals CK of the registers for operating the registers; wherein the input terminal on the R1 is connected to the output terminal of the R6, the output terminals of the other registers are connected to the next input terminals.

Referring to FIGS. 2-5 of the drawings, Reg1 refers to an output result of the high frequency clock CLK1 of the register at a rising edge, CLK2 refers to an output result of the register R4. Referring to the FIG. 2 of the drawings, the output result of the register of the shift frequency demultiplier will be flipped orderly when the high frequency clock CLK1 is at a rising edge. After 6 high frequency clocks CLK1, a cycle is completed, a waveform as shown in the FIG. 2 is formed and the high frequency clock CLK1 is processed with the fractional-6 frequency demultiplier. However, if an intermediate state of the shift register is wrong during working, the inputted high frequency clock CLK1 will not be demultiplied correctly. Specially, referring to the FIG. 3 of the drawings, the intermediate state is wrong, in such a manner that output result of all the registers of the shift frequency demultiplier are 0. As a result, the output terminal of the register R4 outputs a continuous low level signal and the high frequency clock CLK1 cannot be demultiplied. Referring to the FIG. 4 of the drawings, the intermediate state is wrong, in such a manner that output result of all the registers of the shift frequency demultiplier are 1. As a result, the output terminal of the register R4 outputs a continuous high level signal and the high frequency clock CLK1 cannot be demultiplied. Referring to the FIG. 5 of the drawings, the intermediate state is wrong, in such a manner that output result of the registers of the shift frequency demultiplier are discontinuous 0 or 1. As a result, the output terminal of the register R4 outputs an irregular signal and cannot be recovered, which causes the demultiplication error. Therefore, the wrong intermediate state of the conventional shift frequency demultiplier will lead to demultiplication failure or error.

Therefore, for solving the above problems, an improved shift frequency demultiplier should be provided.

### SUMMARY OF THE PRESENT INVENTION

An object of the present invention is to provide a shift frequency demultiplier which has a simple structure in such a manner that less registers and logic devices are needed to fulfill a same requirement of frequency demultiplier, and is able to regain normal frequency demultiplier ability after being disturbed.

Accordingly, in order to accomplish the above objects, the present invention provides a shift frequency demultiplier, which is a fractional-N shift frequency demultiplier, wherein the N is a positive integer larger than or equal to 4; the shift frequency demultiplier comprises:

an inverter;

N-2 registers; and

N-4 OR gates;

wherein each reset terminal of the register is connected to a system reset signal terminal; each clock terminal of the register is connected to an external high frequency clock terminal; an output terminal of the No. N-2 register is connected to an input terminal of the inverter, an output terminal of the inverter is respectively connected to an input terminal of the No. 1 register and input terminals of the OR gates; the OR gates are respectively connected between input terminals and output terminals of the No. 1 register to the No. N-3 register, and the output terminal of the No. 1 register is connected to another input terminal of the No. 1 OR gate, the output terminal of the No. N-4 register is connected to another input terminal of the No. N-4 OR gate; an output terminal of the No. 1 OR gate is connected to the input terminal of the No. 2 register, an output terminal of the No. N-4 OR gate is connected to the input terminal of the No. N-3 register; the output terminal of the No. N-3 register is connected to an input terminal of the No. N-2 register.

Preferable, the N equals to 4; the shift frequency demultiplier comprises:

an inverter;

a first register; and

a second register;

wherein an output terminal of the first register is connected to an input terminal of the second register; an output terminal of the second register is connected to an input terminal of the inverter; an output terminal of the inverter is connected to an input terminal of the first register.

Compared with the conventional technology, the shift frequency demultiplier according to the present invention comprises N-4 the OR gate in such a manner that only N-2 the registers are needed for fractional-N frequency demultiplication. A structure of the shift frequency demultiplier is simplified and is convenient to be realized. Furthermore, the inverter of the shift frequency demultiplier according to the present invention inverts an output result of the No. N-2 register in each clock cycle and inputs the output result into the No. 1 register as well as the OR gates, in such a manner that when an intermediate state of the shift frequency demultiplier is wrong, the shift frequency demultiplier will be recovered within a certain period with a same demultiplication ratio. With the foregoing structure, a scope of application of the shift frequency demultiplier is widened and external distribution on the demultiplication is decreased.

These and other objectives, features, and advantages of the present invention will become apparent from the following detailed description, the accompanying drawings, and the appended claims.

### BRIEF DESCRIPTION OF THE DRAWINGS

FIG. 1 is a schematic view of a circuit of a conventional shift frequency demultiplier utilized in a fractional-6 frequency demultiplier.

FIG. 2 is a waveform outputted by a No. 4 register of the shift frequency demultiplier as shown in the FIG. 1 working correctly.

FIG. 3 is a waveform outputted by the No. 4 register of the shift frequency demultiplier as shown in the FIG. 1 with a first error.

FIG. 4 is a waveform outputted by the No. 4 register of the shift frequency demultiplier as shown in the FIG. 1 with a second error.

FIG. 5 is a waveform outputted by the No. 4 register of the shift frequency demultiplier as shown in the FIG. 1 with a third error.

FIG. 6 is a schematic view of a circuit of a shift frequency demultiplier according to the present invention.

FIG. 7 is a schematic view of a circuit according to a preferred embodiment of the present invention.

FIG. 8 is a waveform outputted by a No. 2 register of the shift frequency demultiplier as shown in the FIG. 7 working correctly.

FIG. 9 is a waveform outputted by the No. 2 register of the shift frequency demultiplier as shown in the FIG. 7 with a first error.

FIG. 10 is a waveform outputted by the No. 2 register of the shift frequency demultiplier as shown in the FIG. 7 with a second error.

FIG. 11 is a waveform outputted by the No. 2 register of the shift frequency demultiplier as shown in the FIG. 7 with a third error.

FIG. 12 is a schematic view of a circuit of a shift frequency demultiplier when N equals to 4 according to the present invention.

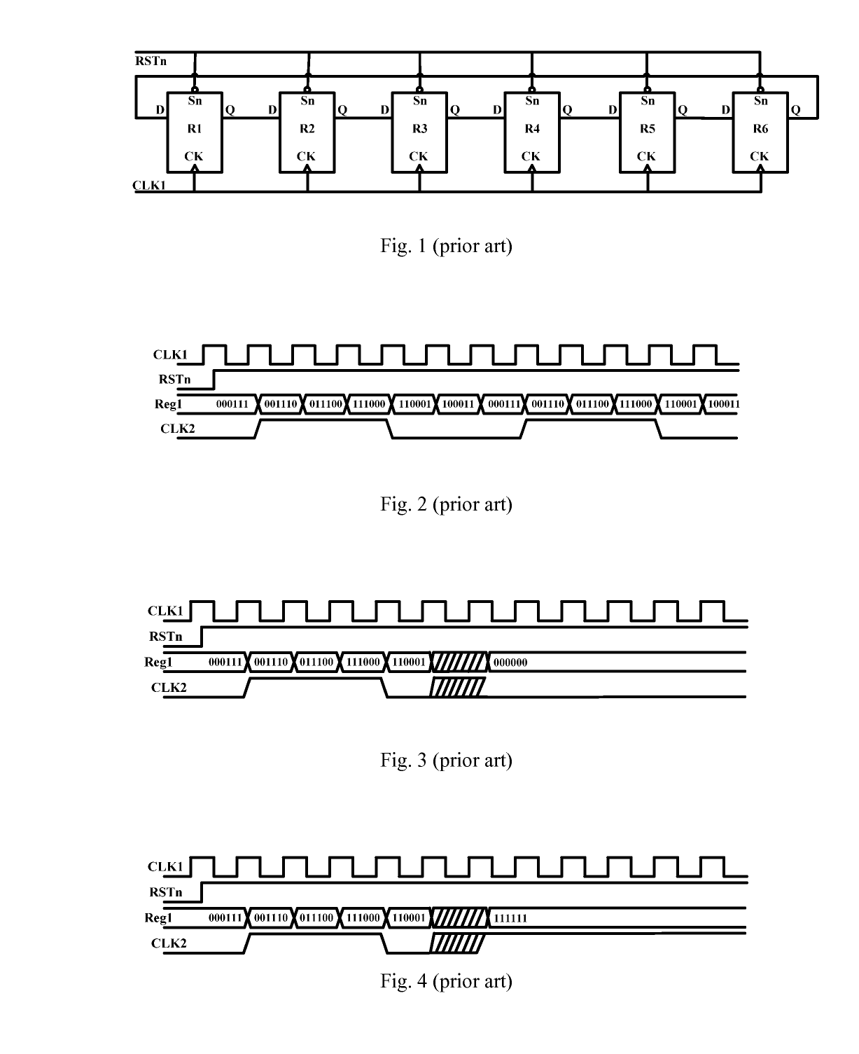

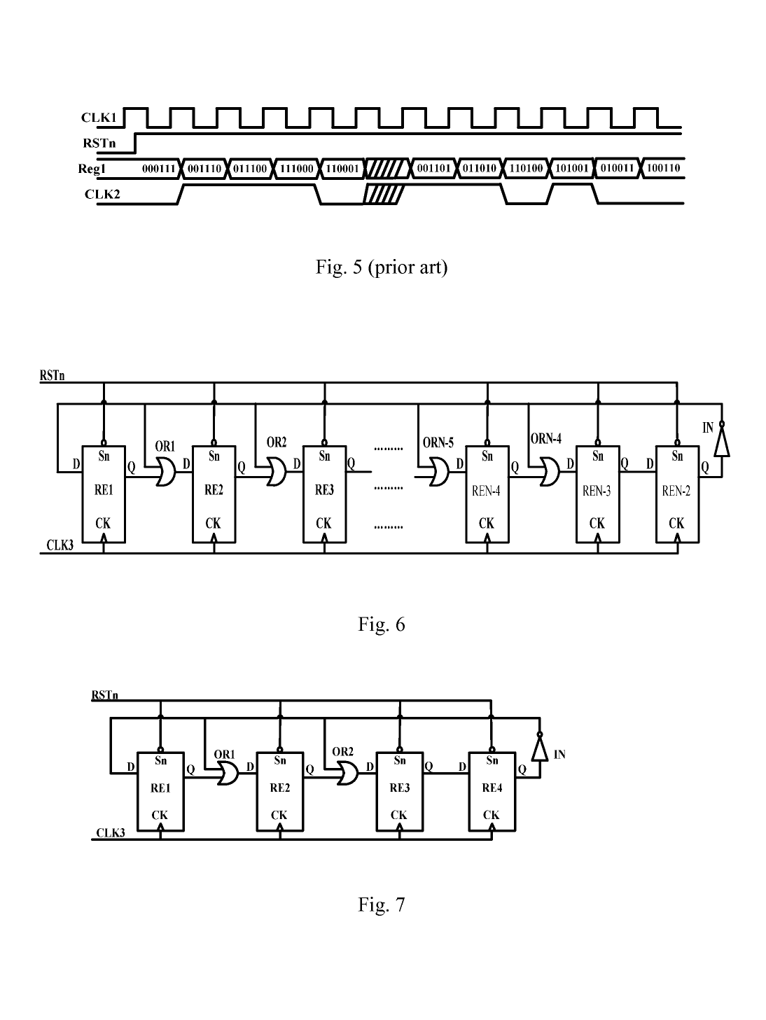

### DETAILED DESCRIPTION OF THE PREFERRED EMBODIMENT

Referring to the drawings, same element numbers refer to same elements. As mentioned above, a shift frequency demultiplier which has a simple structure is provided, in such a manner that less registers and logic devices are needed with a same requirement of frequency demultiplier, and the shift frequency demultiplier is able to regain normal frequency demultiplier ability after being disturbed.

Referring to FIG. 6 of the drawings, a schematic view of a circuit of a shift frequency demultiplier according to the present invention is illustrated. The shift frequency demultiplier according to the present invention comprises:

an inverter IN;

N-2 registers (wherein the No. 1 register is marked as RE1, the No. 2 register is marked as RE2, . . . , and the No. N-2 register is marked as REN-2); and

N-4 OR gates (wherein the No. 1 OR gate is marked as OR1, the No. 2 OR gate is marked as OR2, . . . , and the No. N-4 OR gate is marked as ORN-4);

wherein N, which is a positive integer larger than or equal to 4, is a frequency demultiplier ratio of the shift frequency demultiplier; D is an input terminal of the register, Q is an output terminal of the register, which are the same as in the following drawings; each reset terminal Sn of the register is connected to a system reset signal terminal; the system reset signal terminal sends a system reset signal RSTn to the reset terminal Sn of each of the registers for wholly resetting the registers at an initial state, in such a manner that all the registers are set to 1 or 0, wherein according to the present invention, all the registers are set to 1 by the system reset signal RSTn; each clock terminal CK of the registers is connected to an external high frequency clock terminal; the output terminal of the external high frequency clock terminal sends a high frequency clock CLK3 to the clock terminals CK of the registers for operating the registers; an output terminal of the No. N-2 register REN2 is connected to an input terminal of the inverter IN, an output terminal of the inverter IN is respectively connected to an input terminal of the No. 1 register RE1 and input terminals of the OR gates for inverting an output result of the No. N-2 register REN-2 and inputting the output result into the No. 1 register RE1 as well as the OR gates; the OR gates are respectively connected between input terminals and output terminals of the No. 1 register to the No. N-3 register, and the output terminal of the No. 1 register RE1 is connected to another input terminal of the No. 1 OR gate OR1, the output terminal QN-4 of the No. N-4 register REN-4 is connected to another input terminal of the No. N-4 OR gate ORN-4; an output terminal of the No. 1 OR gate OR1 is connected to the input terminal D2 of the No. 2 register RE2, an output terminal of the No. N-4 OR gate ORN-4 is connected to the input terminal of the No. N-3 register REN-3; the output terminal of the No. N-3 register REN-3 is connected to an input terminal of the No. N-2 register REN-2.

When the shift register works, an initial state of each of the registers is set to 1. The registers shift in turn. And each output result of the registers is reversed and OR-calculated before being inputted into the next register. That is to say, the output result of the No. 1 register RE1 and the output result of the No. N-2 register REN-2 are reversed and are inputted into the No. 2 register RE2 after passing through the No. 1 OR gate OR1; the output result of the No. 2 register RE2 and the output result of the No. N-2 register REN-2 are reversed and are inputted into the No. 3 register RE3 after passing through the No. 2 OR gate OR2; and so forth. By this way, after N clock pulses, the No. N-2 register REN-2 can always completely reset the other registers to the initial state. Thereafter, a cycle of the N states is provided again in such a manner that when an intermediate state of the shift frequency demultiplier is wrong, the shift frequency demultiplier will be recovered within a period for ensuring that the shift frequency demultiplier works normally.

Specifically, referring to FIGS. 7-11 of the drawings, a preferred embodiment 1 of the present invention is provided, wherein the shift frequency demultiplier provides fractional-6 demultiplication to the high frequency clock. The shift frequency comprises:

an inverter IN;

four registers: RE1, RE2, RE3 and RE4; and

two OR gates: OR1 and OR2.

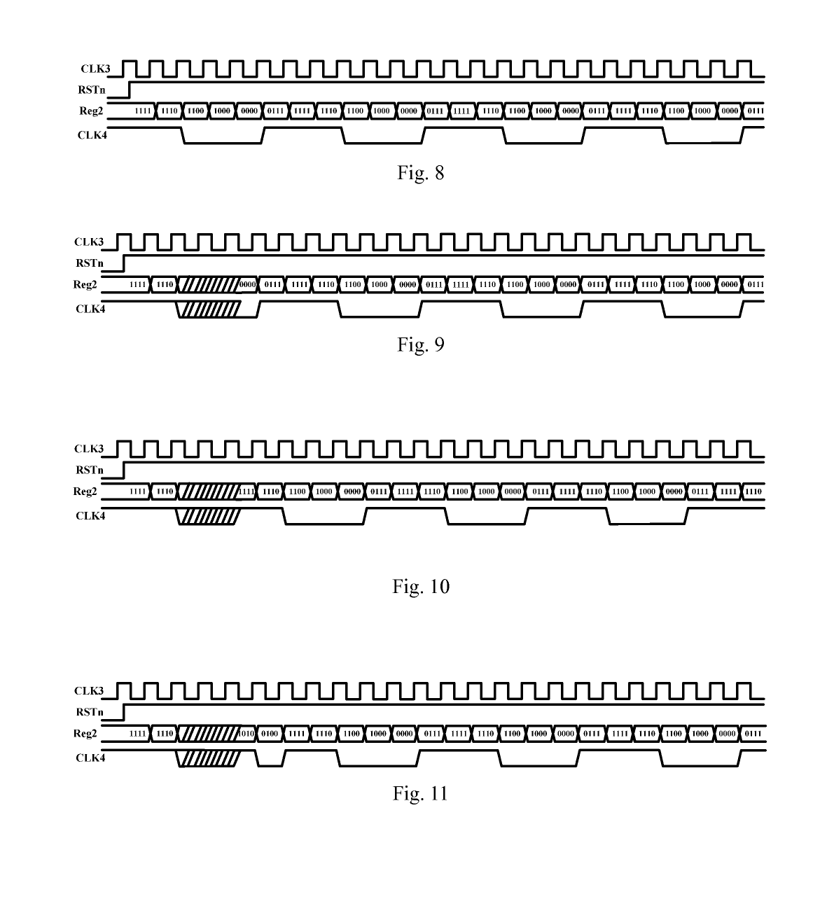

Connection relationship thereof is as shown in the FIG. 7 and will not be further illustrated. Reg2 refers to an output result of the registers RE1, RE2, RE3 and RE4 when the high frequency clock CLK3 is at a rising edge. CLK4 refers to an output result of the register RE2. Referring to the FIG. 8 of the drawings, the output result of the register of the shift frequency demultiplier will be flipped orderly when the high frequency clock CLK3 is at the rising edge. After 6 high frequency clocks CLK1, a cycle is completed. In the cycle, six states of the registers are respectively 1111, 1110, 1100, 1000, 0000 and 0111. The six states are continuously circulated in the following cycles. Referring to the FIG. 8 of the drawings, a waveform of the CLK 4 is a result of the high frequency clock processed with the fractional-6 frequency demultiplication. If an intermediate state of the shift register is wrong during working, the shift frequency demultiplier will be recovered within a certain period for demultiplying the high frequency clock CLK3. Specifically, referring to the FIG. 9 of the drawings, if the intermediate state of the shift register is wrong, in such a manner that the state of the shift frequency demultiplier is 1111, the shift frequency demultiplier will be recovered within a certain period and still provides fractional-6 frequency demultiplier to the high frequency clock CLK 3 because the output result of the register RE4 is reversed and OR-calculated by the inverter IN at the rising edge of the high frequency clock CLK3 and is inputted through the input terminal of the register RE1 and the input terminals of the OR1 and OR2. The result is shown as the waveform of the CLK 4. Therefore, when the intermediate state of the shift frequency demultiplier according to the present invention is wrong and leads to a result that the state of the shift frequency demultiplier is 1111, the shift frequency demultiplier is still able to be recovered and demultiplied correctly. Referring to the FIG. 10 of the drawings, the intermediate state of the shift register is wrong, in such a manner that the state of the shift frequency demultiplier is 0000, the shift frequency demultiplier is still able to be recovered and demultiply correctly. Likewise, referring to the FIG. 11 of the drawings, if the intermediate state is wrong, in such a manner that output result of the registers of the shift frequency demultiplier are discontinuous 0 or 1, the shift frequency demultiplier is still able to be recovered and demultiply correctly.

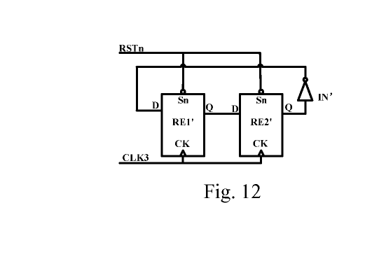

Referring to FIG. 12 of the drawings, a preferred embodiment 2 of the present invention is illustrated, wherein the shift frequency demultiplier provides fractional-4 demultiplication to the high frequency clock CLK3, and the preferred embodiment 2 is similar to the preferred embodiment 1 except for no OR gate involved. Specifically, the shift frequency demultiplier comprises:

an inverter IN′;

a first register RE1′; and

a second register RE2′.

Connection relationship thereof is as shown in the FIG. 7 and will not be further illustrated. Because only the two registers are utilized, the registers have four states: 00, 01, 10 and 11. As a result, even if the intermediate state of the shift frequency demultiplier is wrong, a result is still one of the four states. Therefore, the shift frequency demultiplier according to present invention is able to provide the fractional-4 demultiplication to the high frequency clock CLK3 and will not be affected by the abnormal intermediate state.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

1. A shift frequency demultiplier, which is a fractional-N shift frequency demultiplier, wherein said N is a positive integer larger than or equal to 4; said shift frequency demultiplier comprises:
an inverter;
N-2 registers; and
N-4 OR gates;
wherein when N=5, a No. 1 register is a No. N-4 register; a No. 2 register is a No. N-3 register; and a No. 1 OR gate is a No. N-4 OR gate;
wherein when N=6, said No. 2 register is said No. N-4 register,
wherein each reset terminal of said registers is connected to a system reset signal terminal; each clock terminal of said registers is connected to an external high frequency clock terminal; an output terminal of a No. N-2 register is connected to an input terminal of said inverter, an output terminal of said inverter is respectively connected to an input terminal of said No. 1 register and input terminals of all said OR gates; all said OR gates are respectively connected between input terminals and output terminals of said No. 1 register to said No. N-3 register, and said output terminal of said No. 1 register is connected to another input terminal of said No. 1 OR gate, said output terminal of said No. N-4 register is connected to another input terminal of said No. N-4 OR gate; an output terminal of said No. 1 OR gate is connected to said input terminal of said No. 2 register, an output terminal of said No. N-4 OR gate is connected to said input terminal of said No. N-3 register; said output terminal of said No. N-3 register is connected to an input terminal of said No. N-2 register.

2. The shift frequency demultiplier, as recited in claim 1, wherein the N equals to 4; said shift frequency demultiplier comprises:
an inverter;
a first register comprising a first D flip-flop; and
a second register comprising a second D flip-flop;
wherein an output terminal of said first register is connected to an input terminal of said second register; an output terminal of said second register is connected to an input terminal of said inverter; an output terminal of said inverter is connected to an input terminal of said first register.
